(19) United States
(12) Patent Application Publication
(10) Pub. No.: US 2010/0054130 A1
(43) Pub. Date: Mar. 4, 2010

(54) Data Flow Management Device Transmitting a Plurality of Data Flows

(75) Inventors: Woo-cheol Kwon, Suwon-si (KR); Sung-joo Yoo, Yongin (KR); Sung-min Hong, Seoul (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co.,Ltd., Gyeonggi-do (KR)

(21) Appl. No.: 12/403,363

(22) Filed: Mar. 12, 2009

(30) Foreign Application Priority Data
Aug. 29, 2008 (KR) 10-2008-0085536

(51) Int. Cl. H04J 1/16

(52) U.S. Cl. 370/235

(57) ABSTRACT

Provided is a data flow management device managing a plurality of data flows. The data flow management device transmits data flows received from a plurality of sources to be transmitted to a plurality of destinations. The data flow management device includes a plurality of buffers outputting data flows received from the sources; and a transmitting unit transmitting the data flows output from the buffers to the destinations. The buffers do not output at a same time any two data flows received from two different sources to be transmitted to a same destination.

### CROSS-REFERENCE TO RELATED APPLICATIONS

This application claims priority from Korean Patent Application No. 10-2008-0085536, filed on Aug. 29, 2008, in the Korean Intellectual Property Office, the disclosure of which is incorporated herein in its entirety by reference.

### SUMMARY

The inventive concept relates to a data flow management device, and more particularly, to a data flow management device transmitting a plurality of data flows.

In data flow management devices transmitting data flows from a plurality of sources to a plurality of destinations, when the plurality of destinations access the plurality of sources at the same time, data collision may occur. That is, when a plurality of data flows are transmitted at the same time from the plurality of sources to one destination, collisions between the data flows may occur.

The inventive concept provides a data flow management device which may prevent data collision when data flows are transmitted from a plurality of sources to a plurality of destinations.

According to an aspect of the inventive concept, there is provided a data flow management device managing a plurality of data flows received from a plurality of sources to be transmitted to a plurality of destinations, the data flow management device including: a plurality of buffers receiving the data flows from the sources and outputting the data flows received from the sources; and a transmitting unit transmitting the data flows output from the buffers to the destinations, wherein the buffers do not output to the transmitting unit, at a same time, any two data flows received from two different sources and are to be transmitted to a same destination.

Each buffer may be configured to prevent output of a data flow to be transmitted to a destination that is the same as a destination of another data flow that is set to be output from another buffer.

Each buffer may include an arbitrating unit controlling output of a data flow received at the buffer by using information on a destination of another data flow that is set to be output from another buffer.

Each buffer may include at least one storing unit storing received data flows.

When a plurality of data flows are stored in the storing unit, the arbitrating unit may determine the order of outputting the plurality of data flows.

When each buffer comprises a plurality of storage units, the arbitrating unit may determine the order of outputting the data flow stored in the plurality of storage units.

According to another aspect of the inventive concept, there is provided a data flow management device managing data flows received from a plurality of sources and to be transmitted to a plurality of destinations, the device including: a plurality of buffers receiving the data flows from the sources and outputting the data flows; an arbitrating unit controlling the buffers such that a set of data flows to be transmitted to different destinations are respectively output from each of the buffers at a same time; and a transmitting unit transmitting the set of data flows to the different destinations concurrently.

The arbitrating unit may control the buffers by using information on a destination of each data flow.

### BRIEF DESCRIPTION OF THE DRAWINGS

Exemplary embodiments of the inventive concept will be more clearly understood from the following detailed description taken in conjunction with the accompanying drawings, in which:

FIGS. 1A and 1B are block diagrams of a data flow management devices according to exemplary embodiments;

FIG. 2 is a block diagram of a data flow management device according to another exemplary embodiment;

FIG. 3A is a block diagram of a storing unit of FIG. 1A, 1B or 2, according to an exemplary embodiment;

FIG. 3B is a block diagram of a storing unit of FIG. 1A, 1B or 2, according to another exemplary embodiment; and

FIG. 4 is a block diagram for explaining a transmitting operation of data flows according to an exemplary embodiment, and FIG. 5 is a flowchart for explaining a method of data flow management, according to another exemplary embodiment.

### DETAILED DESCRIPTION OF EXEMPLARY EMBODIMENTS

Hereinafter, exemplary embodiments of the inventive concept are explained with reference to the attached drawings. Like reference numerals in the drawings denote like elements.

The term “unit”, as used herein, may include, but is not limited to, a software or hardware component, such as a Field Programmable Gate Array (FPGA) or Application Specific Integrated Circuit (ASIC), which performs certain tasks. A unit may be configured to reside on the addressable storage medium and configured to execute on one or more processors. Thus, a unit may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionality provided for in the components and units may be combined into fewer components and units or further separated into additional components and units. In addition, the components and units may be implemented such that they execute one or more computers in a communication system.

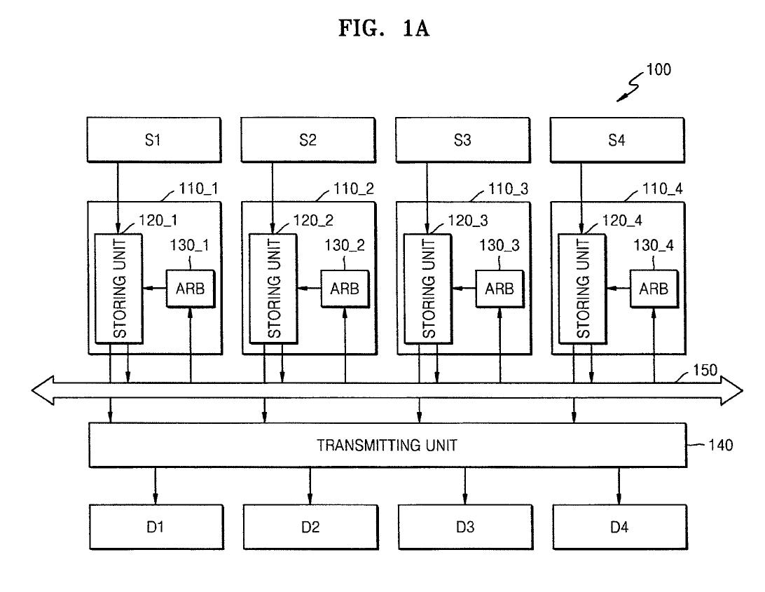

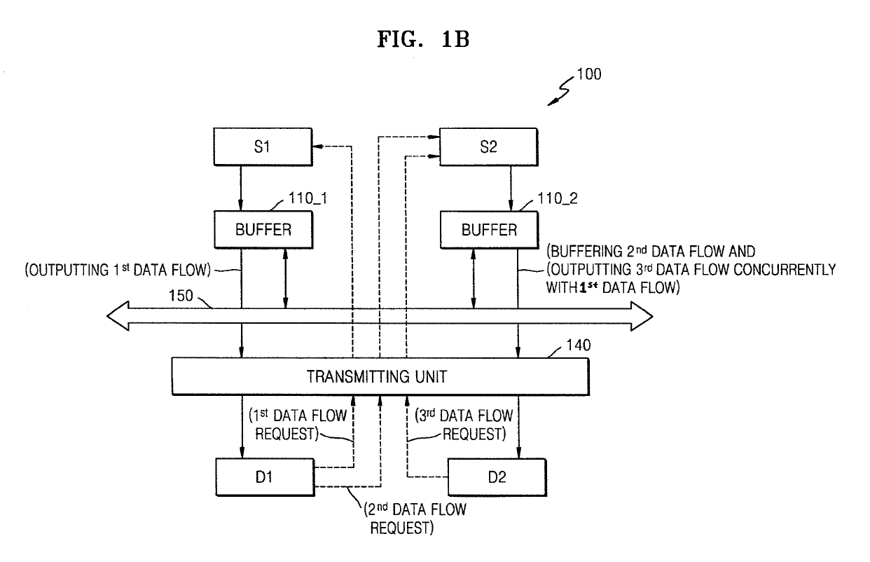

FIG. 1A is a block diagram of a data flow management device 100 according to an exemplary embodiment. The data flow management device may be implemented as a semiconductor device although the inventive concept is not limited thereto.

Referring to FIG. 1A, the data flow management device 100 transmitting data flows from a plurality of sources S1, S2, S3 and S4 to a plurality of destinations D1, D2, D3 and D4 may include a plurality of buffers 110_1, 110_2, 110_3 and 110_4 and a transmitting unit 140. FIG. 1A illustrates a case in which the data flow management device 100 includes the first through fourth sources S1, S2, S3 and S4, the first through fourth destinations D1, D2, D3 and D4, and the first through fourth buffers 110_1, 110_2, 110_3 and 110_4, but the exemplary embodiments of the inventive concept are not limited thereto. Even if the data flow management device 100 includes different numbers of sources, destinations and buffers, it may obtain the same effect as the current exemplary embodiment.

The plurality of buffers 110_1, 110_2, 110_3 and 110_4 buffer and output data flows received from the corresponding sources S1, S2, S3 and S4. For example, the first buffer 110_1 buffers and outputs a data flow received from the first source S1, and the second buffer 110_2 buffers and outputs a data flow received from the second source S2. The third buffer 110_3 buffers and outputs a data flow received from the third source S3, and the fourth buffer 110_4 buffers and outputs a data flow received from the fourth source S4.

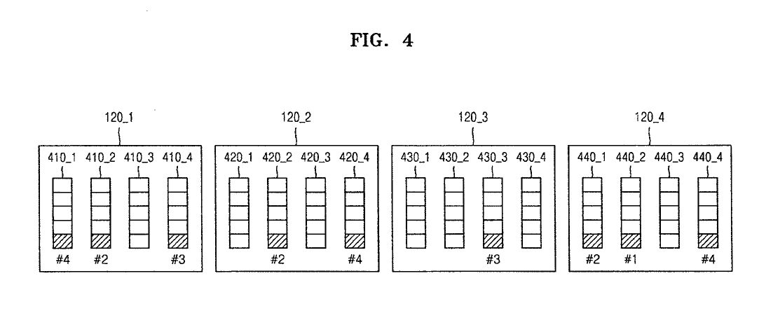

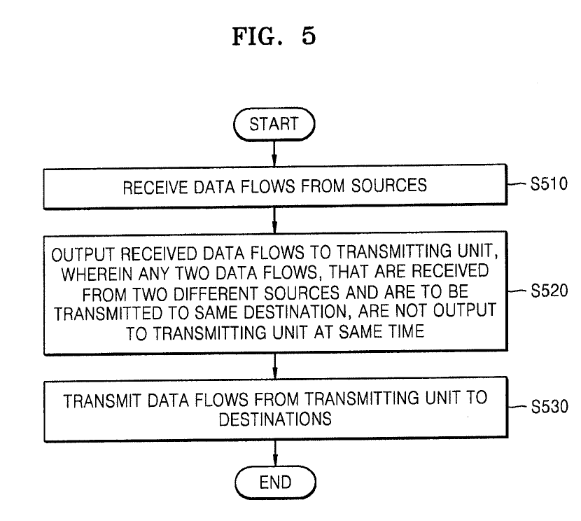

Each of the first through fourth buffers 110_1, 110_2, 110_3 and 110_4 outputs a data flow to be transmitted to a destination different from a destination of another data flow that is output from a different buffer. Each of the first through fourth buffers 110_1, 110_2, 110_3 and 110_4 prevents a data flow from being transmitted to a destination that is the same as a destination of another data flow that is output from a different buffer. For example, as shown in FIG. 1B, when a first data flow is set to be output from the first buffer 110_1 to the transmitting unit 140 in order to be transmitted to the first destination D1, the second buffer 110_2 may prevent output of a second data flow set to be output to the transmitting unit 140 to be transmitted to the first destination D1, and instead, may output a third data flow to be transmitted to the second destination D2 concurrently with the first data flow. The second data flow may be output to the transmitting unit 140 to be transmitted to the destination D1 later when no collisions with other data flows are expected. In this example, the first and second data flows may have been received at the first and second buffers 110_1 and 110_2 substantially at the same time from the first and second sources S1 and S2, in response to first and second data flow requests from the first destination D1 to the first and second sources S1 and S2, respectively. The first and second data flow requests may have been output from the destination D1 consecutively. The third data flow may have been received at the second buffer 110_2 in response to third data flow request transmitted from the second destination D2 to the second source S2. The first, second and third data flow requests may have been transmitted from the first and second destinations D1 and D2 to the first and second sources S1 and S2 directly or through the transmitting unit 140. Operations of the above buffers will be described in detail later with reference to FIG. 4.

The first buffer 110_1 may include a first storing unit 120_1 and a first arbitrating unit 130_1. The first storing unit 120_1 may store a data flow received from the first source S1. The first arbitrating unit 130_1 controls whether to output the data flow stored in the first storing unit 120_1 by using destination information corresponding to data flows that are respectively output from the second through fourth buffers 110_2 through 110_4. Similar to the first buffer 110_1 the second buffer 110_2 may include a second storing unit 120_2 and a second arbitrating unit 130_2. The second storing unit 120_2 may store a data flow received from the second source S2. The second arbitrating unit 130_2 controls whether to output the data flow stored in the second storing unit 120_2 by using destination information corresponding to data flows that are respectively output from the first buffer 110_1, the third buffer 110_3 and the fourth buffer 110_4. Also, the third buffer 110_3 may include a third storing unit 120_3 and a third arbitrating unit 130_3, and the fourth buffer 110_4 may include a fourth storing unit 120_4 and a fourth arbitrating unit 130_4. The third storing unit 120_3 may store a data flow received from the third source S3. The third arbitrating unit 130_3 controls whether to output the data flow stored in the third storing unit 120_3 by using destination information corresponding to data flows that are respectively output from the first buffer 110_1, the second buffer 110_2 and the fourth buffer 110_4. The fourth storing unit 120_4 may store a data flow received from the fourth source S4. The fourth arbitrating unit 130_4 controls whether to output the data flow stored in the fourth storing unit 120_4 by using destination information corresponding to data flows that are respectively output from the first through third buffers 110_1 through 110_3. The destination information may be transmitted via a bus 150 to the first through fourth buffers 110_1 through 110_4, and the destination information may be a destination identifier (ID). According to an exemplary embodiment, the bus 150 may be a bus dedicated to transmitting the destination information. An operation of an arbitrating unit such as the arbitrating units 130_1, 130_2, 130_3 and 130_4 using the destination information will be described in detail later with reference to FIG. 4.

The transmitting unit 140 may transmit data flows that are output from the buffers 110_1, 110_2, 110_3 and 110_4 to corresponding destinations D1, D2, D3 and D4. For example, in the case that the first buffer 110_1 outputs a first data flow to be transmitted to the second destination D2, and the second buffer 110_2 outputs a second data flow to be transmitted to the third destination D3, the transmitting unit 140 transmits the first data flow that is output from the first buffer 110_1 to the second destination D2, and transmits the second data flow that is output from the second buffer 110_2 to the third destination D3. According to an exemplary embodiment, the transmitting unit 140 may be implemented as a bus.

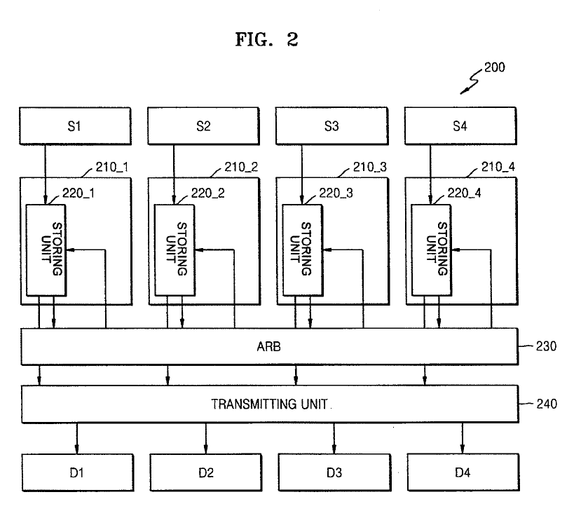

FIG. 2 is a block diagram of a data flow management device 200 according to another exemplary embodiment.

Referring to FIG. 2, the data flow management device 200 transmitting data flows from a plurality of sources S1, S2, S3 and S4 to a plurality of destinations D1, D2, D3 and D4 may include a plurality of buffers 210_1, 210_2, 210_3 and 210_4 and a transmitting unit 240. Similar to FIG. 1A, FIG. 2 illustrates a case in which the data flow management device 200 includes first through fourth sources S1 through S4, first through fourth destinations D1 through D4, and first through fourth buffers 210_1 through 210_4, but the exemplary embodiments of the inventive concept are not limited thereto. Even if the data flow management device 200 includes different numbers of sources, destinations and buffers, it may obtain the same effect as the current exemplary embodiment.

The buffers 210_1 through 210_4 buffer and output data flows received from the sources S1 through S4. For example, the first buffer 210_1 buffers and outputs a data flow received from a first source S1, and the second buffer 210_2 buffers and outputs a data flow received from a second source S2. Also, the third buffer 210_3 buffers and outputs a data flow received from a third source S3, and the fourth buffer 210_4 buffers and outputs a data flow received from a fourth source S4.

The first buffer 210_1 may include a first storing unit 220_1 storing the data flow received from the first source S1, and the second buffer 210_2 may include a second storing unit 220_2 storing the data flow received from the second source S2. Also, the third buffer 210_3 may include a third storing unit 220_3 storing the data flow received from the third source S3, and the fourth buffer 210_4 may include a fourth storing unit 220_4 storing the data flow received from the fourth source S4.

An arbitrating unit 230 controls the first through fourth buffers 210_1 through 210_4 so that a plurality of data flows that are output from the first through fourth buffers 210_1 through 210_4 are transmitted to different destinations. That is, the arbitrating unit 230 may prevent a plurality of data flows that are set to be transmitted to the same destination from being simultaneously output from two or more buffers from among the first through fourth buffers 210_1 through 210_4. For example, when data flows are simultaneously output from the first and second buffers 210_1 and 210_2 to the fourth destination D4, the arbitrating unit 230 may control the data flows such that only the first buffer 210_1 outputs a data flow to be transmitted to the fourth destination D4 according to a given priority order, and the second buffer 210_2 outputs a data flow that is to be transmitted to a different destination instead of to the fourth destination D4. An operation of the arbitrating unit 230 will be described in detail later with reference to FIG. 4.

A transmitting unit 240 may transmit data flows that are output from the buffers to corresponding destinations, similar to the transmitting unit 140 of FIGS. 1A and 1B.

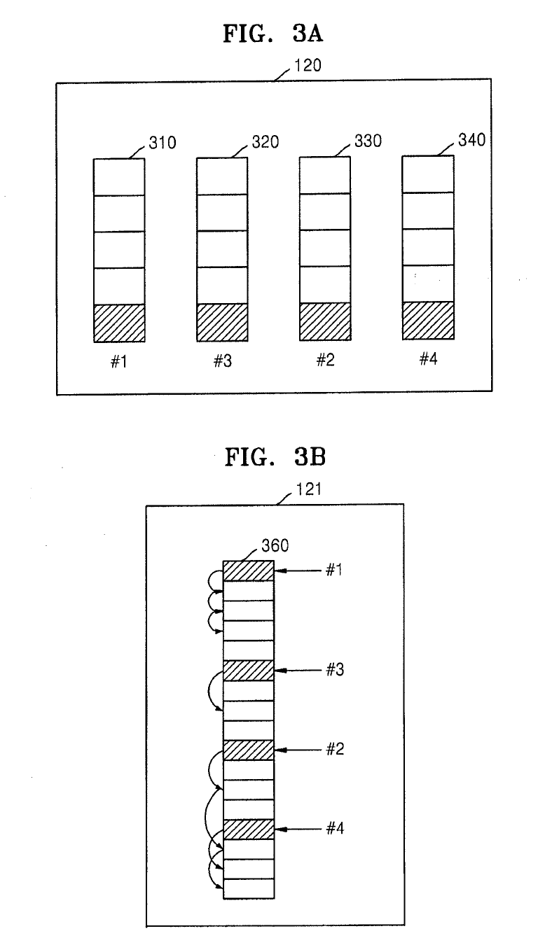

FIG. 3A is a block diagram of a storing unit 120 corresponding to each of the first through fourth storing units 120_1 through 120_4 of FIG. 1A or each of the first through fourth storing units 220_1 through 220_4 of FIG. 2 according to an exemplary embodiment.

Referring to FIG. 1A through FIG. 3A, the FIFO storing unit may include a plurality of storage units 310, 320, 330 and 340. FIG. 3A illustrates the case in which the storing unit 120 includes the first through fourth storage units 310 through 340, but the present inventive concept is not limited thereto. Even if the storing unit 120 includes different numbers of storage units, it may obtain a same effect as the current exemplary embodiment. #1, #2, #3 and #4 represent destination information. For example, since the destination information of a data flow stored in a first storage unit 310 is #1, the data flow may be transmitted to the first destination D1. Since the destination information of a data flow stored in the second storage unit 320 is #3, the data flow may be transmitted to the third destination D3. Similarly, since the destination information of a data flow stored in the third storage unit 330 is #2, the data flow may be transmitted to the second destination D2. Since the destination information of a data flow stored in the fourth storage unit 340 is #4, the data flow may be transmitted to the fourth destination D4.

FIG. 3B is a block diagram of the storing unit 121 of corresponding to each of the first through fourth storing units 120_1 through 120_4 of FIG. 1A or each of the first through fourth storing units 220_1 through 220_4 of FIG. 2, according to another exemplary embodiment.

Referring to FIGS. 1A, 2 and 3B, the storing unit 120 may include a storage unit 360. The storage unit 360 may store a plurality of data flows, and one data flow may be managed as a linked list separated in the storage unit 360. Similarly to FIG. 3A, #1, #2, #3 and #4 represent destination information. If a data flow having destination information #1 is to be transmitted to a first destination D1, a data flow having destination information #2 is to be transmitted to a second destination D2, a data flow having destination information #3 is to be transmitted to a third destination D3, and a data flow having destination information #4 is to be transmitted to a fourth destination D4, the data flow to be transmitted to the first destination D1 may be stored at a position of the destination information #1 in an arrow direction (as indicated by an arrow shown in FIG. 3B) in the storage unit 360. The data flow to be transmitted to the second destination D2 may be stored at a position of the destination information #2 in an arrow direction (as indicated by an arrow shown in FIG. 3B) in the storage unit 360. Also, the data flow to be transmitted to the third destination D3 may be stored at a position of the destination information #3 in an arrow direction (as indicated by an arrow shown in FIG. 3B) in the storage unit 360, and the data flow to be transmitted to the fourth destination D4 may be stored at a position of the destination information #4 in an arrow direction (as indicated by an arrow shown in FIG. 3B) in the storage unit 360.

FIG. 3B illustrates a case in which a data flow is managed as the linked list, but the present inventive concept is not limited thereto. If a plurality of data flows can be managed in one storage unit 360 in another manner different from the above, it may obtain a same effect as the current exemplary embodiment. For example, the storage unit 360 is divided into regions, so that a plurality of data flows can be stored in corresponding regions.

FIG. 4 is a block diagram for explaining a transmitting operation of data flows according to an exemplary embodiment.

In the current exemplary embodiment, first through fourth storing units 120_1 through 120_4 of FIG. 4 are the first through fourth storing units 120_1 through 120_4 of FIG. 1A. The first storing unit 120_1 includes first through fourth storage units 410_1 through 410_4, and the second storing unit 120_2 includes fifth through eighth storage units 420_1 through 420_4. The third storing unit 120_3 includes ninth through twelfth storage units 430_1 through 430_4, and that the fourth storing unit 120_4 includes thirteenth through sixteenth storage units 440_1 through 440_4.

Also in the current exemplary embodiment, data flows stored in the first through fourth storing units 120_1 through 120_4 are transmitted to destinations D1 through D4 corresponding to destination information. That is, a stored data flow is transmitted to a first destination D1 when destination information is #1, a stored data flow is transmitted to a second destination D2 when destination information is #2, a stored data flow is transmitted to a third destination D3 when destination information is #3, and a stored data flow is transmitted to a fourth destination D4 when destination information is #4. Therefore, the first storage unit 410_1 stores a data flow to be transmitted to the fourth destination D4, the second storage unit 410_2 stores a data flow to be transmitted to the second destination D2, and the fourth storage unit 410_4 stores a data flow to be transmitted to the third destination D3. Similarly, the sixth storage unit 420_2, the eighth storage unit 420_4, the eleventh storage unit 430_3, the thirteenth storage unit 440_1, the fourteenth storage unit 440_2 and the sixteenth storage unit 440_4 store data flows to be respectively transmitted to the second destination D2, the fourth destination D4, the third destination D3, the second destination D2, the first destination D1 and the fourth destination D4. The third storage unit 410_3, the fifth storage unit 420_1, the seventh storage unit 420_3, the ninth storage unit 430_1, the tenth storage unit 430_2, the twelfth storage unit 420_4 and the fifteenth storage unit 440_3 that do not have destination information are in a state where no data flows are stored.

Similar to FIG. 4, when the first through fourth storing units 120_1 through 120_4 include the storage units 410_1 through 410_4, 420_1 through 420_4, 430_1 through 430_4 and 440_1 through 440_4, respectively, the first through fourth arbitrating units 130_1 through 130_4 determine orders of output of data flows stored in the corresponding storage units 410_1 through 410_4, 420_1 through 420_4, 430_1 through 430_4 and 440_1 through 440_4, respectively. That is, the first arbitrating unit 130_1 determines an output order of data flows stored in the first through fourth storage units 410_1 through 410_4, and the second arbitrating unit 130_2 determines an output order of data flows stored in the fifth through eighth storage units 420_1 through 420_4. Also, the third arbitrating unit 130_3 determines an output order of data flows stored in the ninth through twelfth storage units 430_1 through 430_4, and the fourth arbitrating unit 130_4 determines an output order of data flows stored in the thirteenth through sixteenth storage units 440_1 through 440_4. These orders determined by the first through further arbitrating units may be referred to as local priority orders.

For example, the first arbitrating unit 130_1 determines a local priority order of destination information as #2-#3-#1-#4, the second arbitrating unit 130_2 determines a local priority order of destination information as #2-#4-#1-#3, the third arbitrating unit 130_3 determines a local priority order of destination information as #3-#2-#4-#1, and the fourth arbitrating unit 130_3 determines a local priority order of destination information as #4-#1-#2-#3. The local priority order of the destination information becomes higher toward the left side of the above destination information. The local priority order of the destination information is arbitrarily determined for convenience of description, and the local priority order may vary as required. As described above, a method of arbitrating output of data flows by fixing the local priority order is called a fixed priority arbitration method. Also, an arbitration method may use a round robin arbitration method or a latency-based arbitration method. The round robin arbitration method is a method in which an output order of data flows is not fixed and a data flow is output whenever received. The latency-based arbitration method determines a local priority order on the basis of a waiting time until a data flow is output after being received. Even though any arbitration method may be used, a same effect as the current exemplary embodiment can be obtained.

The first through fourth arbitrating units 130_1 through 130_4 may control the first through fourth buffers 110_1, 110_2, 110_3 and 110_4 such that whether these buffers should output data flows or not by using one arbitration method from among the above arbitration methods. For example, that the first through fourth arbitrating units 130_1 through 130_4 may determine a priority order in the order of the first buffer 110_1—the second buffer 110_2—the third buffer 110_3—the fourth buffer 110_4. This priority order between the buffers may be referred to as a global priority order. The global priority order of the buffers becomes higher toward the left side of the buffers.

Hereinafter, an operation of a data flow management device 100 will be described according to the global and local priority orders taken as examples above. First, according to the local priority order of the destination information, the first buffer 110_1 is set to output a data flow having the destination information #2, the second buffer 110_2 is set to output a data flow having the destination information #2, the third buffer 110_3 is set to output a data flow having the destination information #3, and the fourth buffer 110_4 is set to output a data flow having the destination information #4. Here, both the first buffer 110_1 and the second buffer 110_2 are set to output the data flows having the destination information #2. However, since the first buffer 110_1 has a higher global priority order than the second buffer 110_2, only the first buffer 110_1 outputs the data flow having the destination information #2. That is, the first arbitrating unit 130_1 controls the first storing unit 120_1 to output the data flow having the destination information #2, and the second arbitrating unit 130_2 controls the second storing unit 120_2 to prevent output of the data flow having the destination information #2. Therefore, the second buffer 110_2 outputs the data flow having the destination information #4 according to the local priority order of the destination information. However, in this case, since the second buffer 110_2 and the fourth buffer 110_2 equally output the data flows having the destination information #4, only the second buffer 110_2 outputs the data flow having the destination information #4 according to the global priority order between the buffers. The fourth buffer 110_4 outputs the data flow having the destination information is #1 according to the local priority order of the destination information. Accordingly, the first buffer 110_1 outputs the data flow having the destination information #2, the second buffer 110_2 outputs the data flow having the destination information #4, the third buffer 110_3 outputs the data flow having the destination information #3, and the fourth buffer 110_4 outputs the data flow having the destination information #1. Here, these data flows may be concurrently output from the respective buffers to the transmitting unit 140. In addition, these data flows may be concurrently transmitted to the respective destinations.

Examining the state after the first output is finished, according to the local priority order of the destination information, the first buffer 110_1 is set to output the data flow having the destination information #3, the second buffer 110_2 is set to output the data flow having the destination information #2, and the fourth buffer 110_4 is set to output the data flow having the destination information #4. In this case, since the first buffer 110_1, the second buffer 110_2 and the fourth buffer 110_4 respectively are set to output data flows having different destination information, the first buffer 110_1 outputs the data flow having the destination information #3, the second buffer 110_2 outputs the data flow having the destination information #2, and the fourth buffer 110_4 outputs the data flow having the destination information #4, without an additional arbitration. Here, these data flows may be concurrently output from the respective buffers to the transmitting unit 140. In addition, these data flows may be concurrently transmitted to the respective destinations.

Examining the state after the second output is finished, according to the local priority order of the destination information, the first buffer 110_1 is set to output the data flow having the destination information #4, and the fourth buffer 110_4 is set to output the data flow having the destination information #2. In this case, since the first buffer 110_1 and the fourth buffer 110_4 respectively are set to output data flows of different destination information, the first buffer 110_1 outputs the data flow having the destination information #4, and the fourth buffer 110_4 outputs the data flow having the destination information #2, without an additional arbitration. Here, these data flows may be concurrently output from the respective buffers to the transmitting unit 140. In addition, these data flows may be concurrently transmitted to the respective destinations. In the meantime, referring to FIG. 4, the data flow having the destination information #2 in the storage unit 410_2 of the first storing unit 120_1 of the first buffer 110_1 has the highest global priority order as well as the highest local priority order. Thus, according to another exemplary embodiment, since the data flow having the destination information #2 in the storage unit 410_2 may be output to the transmitting unit 140 without being buffered in the storage unit 410_2 when received at the first buffer 110_1.

According to an exemplary embodiment, transmission of data flows and control of buffers are performed at the same time by using a local priority order of destination information of each buffer and a global priority order between the buffers, so that the data flows that are respectively output from each buffer can be prevented from being simultaneously transmitted to the same destination. Thus, the present inventive concept can be also applied to a system-on-chip which uses a plurality of memory ports, such as a three-dimensional (3D) stacked memory, in which case the sources S1 through S4 as shown in FIG. 1A may be corresponding memory modules of the 3-D stacked memory, and the data flows may be output from the sources in response to memory read requests from the destinations. Here, the memory modules may include Double Data Rate (DDR) random access memories.

In the above description, the data flow management device 100 of FIG. 1A has been described. However, since the arbitrating unit 230 functions as the first through fourth arbitrating units 130_1 through 130_4 of FIG. 1A, the data flow management device 200 of FIG. 2 may also operate in the same manner as described above.

Also, FIG. 4 illustrates the case in which the storing unit includes a plurality of storage units as illustrated in FIG. 3A. However, as illustrated in FIG. 3B, when the storing unit includes one storage unit and a plurality of data flow are stored in the one storage unit, the storing unit of FIG. 3B may operate in the same manner as described above with reference to FIG. 4 by using a local priority order of destination information. When the storing unit is formed as illustrated in FIG. 3B, the local priority order of the destination information may be determined using a fixed priority arbitration method, a round robin arbitration method, or a latency-based arbitration method. Alternatively, the local priority order may be determined with respect to only partial destination information from among destination information #1, #2, #3 and #4. For example, the priority order of the destination information is determined as #1-#2, and it may be determined that a data flow of destination information #3 is output after outputting a data flow of destination information #1 and a data flow of destination information #4 is output after outputting a data flow of destination information #2. In this case, if there is no collision with a data flow that is output from a different buffer, the data flow of the destination information #1 is firstly output without being stored in the buffer and then the data flow of the destination information #3 is output, according to the local priority order of the destination information. Next, the data flow of the destination information #2 is output and then finally the data flow of the destination information #4 is output, according to the local priority order of the destination information.

According to the exemplary embodiments of a data flow management device transmitting a plurality of data flows, when data flows are transmitted from a plurality of sources to a plurality of destinations, transmission and control of the data flows are performed at the same time, so that data collision can be effectively prevented. According to another exemplary embodiment as illustrated in FIG. 5, a method of data flow management in a network comprising a plurality of sources, a plurality of buffers, a transmitting unit and a plurality of destinations is provided. The method includes receiving at the plurality of buffers data flows from the sources (S510). The method further includes outputting the received data flows to the transmitting unit such that any two data flows, that are received from two different sources among the plurality of sources and are to be transmitted to a same destination among the destinations, are not output from the buffers to the transmitting unit at a same time (S520), and transmitting the data flows that are output from the buffers to the destinations from the transmitting unit to the destinations (S530).

While the inventive concept has been particularly shown and described with reference to the exemplary embodiments thereof, it will be understood that various changes in form and details may be made therein without departing from the spirit and scope of the following claims.

1. A data flow management device managing a plurality of data flows that are received from a plurality of sources and are to be transmitted to a plurality of destinations, the data flow management device comprising:
a plurality of buffers that receive the data flows from the sources and output the data flows that are received from the sources; and
a transmitting unit that transmits the data flows that are output from the buffers to the destinations,
wherein the buffers do not output to the transmitting unit, at a same time, any two data flows that are received from two different sources among the sources and are to be transmitted to a same destination among the destinations.

2. The data flow management device of claim 1, wherein if a first buffer of the buffers receives a first data flow to be transmitted to a destination, a second buffer receives a second data flow to be transmitted to the destination, and the first and second data flows are both set to be output to the transmitting unit at a first time, the second buffer prevents output of the second data flow to the transmitting unit at the first time and the first buffer outputs the first data flow to the transmitting unit at the first time.

3. The data flow management device of claim 2, wherein if the first buffer receives the first data flow to be transmitted to the destination, the second buffer receives the second data flow to be transmitted to the destination, and the first and second data flows are both set to be output to the transmitting unit at the first time, the second data flow prevented from being output to the transmitting unit is buffered in the second buffer and output to the transmitting unit at a second time subsequent to the first time to be transmitted to the first destination.

4. The data flow management device of claim 3, wherein if a third data flow to be transmitted to another destination is stored in the second buffer at the first time, the third data flow is concurrently output to the transmitting unit with the first data flow at the first time.

5. The data flow management device of claim 1, wherein each buffer comprises an arbitrating unit that controls whether to output a data flow received at the buffer by using information on a destination of another data flow that is set to be output from another buffer to the transmitting unit.

6. The data flow management device of claim 1, further comprising at least one arbitrating unit that controls whether to output a data flow received at a buffer of the buffers to the transmitting unit by using information on a destination of another data flow that is set to be output from another buffer to the transmitting unit.

7. The data flow management device of claim 6, wherein the information on the destination of the second data flow is transmitted from the other buffer to the arbitrating unit through a bus dedicated to transmitting the information on the destinations of the data flows.

8. The data flow management device of claim 6, wherein the arbitrating unit controls the buffers to output the data flows to the transmitting unit by using a global priority order between the buffers.

9. The data flow management device of claim 8, wherein the arbitrating unit controls the buffers to output the data flows to the transmitting unit by using a local priority order between data flows received at a same buffer, and
wherein the local priority order is determined based on destinations of the data flows received at the same buffer.

10. The data flow management device of claim 1, further comprising at least one arbitrating unit,
wherein each of the buffers comprises at least one storage unit storing at least two data flows that are received from at least one of the sources and are to be transmitted to at least one of the destinations, and
wherein the at least one arbitrating unit determines a local priority order of outputting the at least two data flows to be output from the storage unit to the transmitting unit based on the at least one of the destinations.

11. The data flow management device of claim 10, wherein the at least one arbitrating unit determines a global priority order for outputting another at least two data flows received at different buffers.

12. The data flow management device of claim 1, wherein the buffers concurrently output to the transmitting unit data flows to be transmitted to different destinations.

13. The data flow management device of claim 1, wherein at least one of the buffers outputs to the transmitting unit a data flow received from one of the sources without buffering the data flow within the at least one buffer, if the data flow is determined not to be transmitted to a destination that is the same as a destination of another data flow received from another source, and if there is not any data flow that is set to be output from the at least one of the buffers to the transmitting unit before the data flow.

14. The data flow management device of claim 1, wherein the transmitting unit comprises a bus.

15. The data flow management device of claim 1, wherein the sources are memory modules, and the data flows are output from the sources by memory read requests from the destinations.

16. An on-chip network comprising the data flow management device of claim 1, wherein the sources are memory modules of a three-dimensional (3D) stacked memory.

17. An on-chip network comprising the data flow management device of claim 1, wherein the sources are Double Data Rate (DDR) random access memories.

18. A data flow management device managing data flows that are received from a plurality of sources and are to be transmitted to a plurality of destinations, the data flow management device comprising:
a plurality of buffers that receive the data flows from the sources and output the data flows that are received from the sources;
an arbitrating unit that controls the buffers so that a set of data flows to be transmitted to different destinations are respectively output from each of the buffers at a same time; and
a transmitting unit that transmits concurrently the set of data flows that are output from the buffers to the different destinations.

19. The data flow management device of claim 18, wherein the buffers output the set of data flows according to a local priority order determined based on which destinations the set of data flows are to be transmitted to and a global priority order determined based on at which buffers the set of data flows are received so that the set of data flows that are concurrently output from the buffers have different destinations.

20. A method of data flow management in a network comprising a plurality of sources, a plurality of buffers, a transmitting unit and a plurality of destinations, the method comprising:
receiving at the plurality of buffers data flows from the sources and outputting the received data flows to the transmitting unit; and
transmitting the data flows that are output from the buffers to the destinations from the transmitting unit to the destinations,
wherein any two data flows, that are received from two different sources among the plurality of sources and are to be transmitted to a same destination among the destinations, are not output from the buffers to the transmitting unit at a same time.
